(19) United States
(12) Patent Application Publication
(10) Pub. No.: US 2004/0175877 A1
(43) Pub. Date: Sep. 9, 2004

(54) Method of forming a bottle-shaped trench

(76) Inventors: Shian-Jyh Lin, Chiayi Hsien (TW); Chen-Chou Huang, Taipei (TW); Ming-Cheng Chang, Taoyuan Hsien (TW); Hsien-Hao Liao, Taichung (TW); Meng-Hung Chen, Taoyuan (TW)

Correspondence Address: QUINTERO LAW OFFICE, 1617 BROADWAY, 3RD FLOOR, SANTA MONICA, CA, 90404, US

(21) Appl. No.: 10/783,359

(22) Filed: Feb. 20, 2004

(30) Foreign Application Priority Data
Mar. 6, 2003 (TW) 92104769

(51) Int. Cl. H01L 29/94

(52) U.S. Cl. 438/200

(57) ABSTRACT

A method of forming a bottle-shaped trench. A trench is formed in a substrate, wherein the trench has a surface with an upper portion and a lower portion beneath the upper portion. A dielectric layer is formed on the trench surface at the lower portion. Using the dielectric layer as a mask, a nitridation procedure is performed to form a nitride film on the trench surface at the upper portion. The dielectric layer is removed. Using the nitride film as a mask, an isotropic etching procedure is performed to form a space in the trench at the lower portion. Thus, a bottle-shaped trench is formed.

### BACKGROUND OF THE INVENTION

1. Field of the Invention

The present invention relates to a method of fabricating a trench capacitor, and more particularly, to a method of forming a bottle-shaped trench.

2. Description of the Related Art

As the integration density of Dynamic Random Access Memory (DRAM) steadily increases, it becomes necessary to reduce the size of the memory cell. Memory cell size is primarily determined by the minimum resolution dimension of the lithographic technique, the overlay tolerance between the different features and the layout of these features. At the same time, it is necessary to maintain the minimum required storage capacitance to reliably operate the DRAM. In order to meet both the cell size and storage capacitance requirements, a trench was invented. Therefore, the simple single device/capacitor memory cell has been altered so that the capacitor may be positioned vertically. In such a design, the capacitor is formed in a trench in the surface of the semiconductor substrate.

In the memory cell, a deep trench is formed in a silicon substrate in a direction perpendicular to the main surface thereof and a memory capacitor is typically formed on the sidewall of the trench. The method of fabricating a semiconductor memory device with a capacitor on the side surface of the trench is well known in the prior art.

As the size of a DRAM is scaled down by a factor of feature size, however, the trench storage node capacitance decreases by the factor of feature size. Therefore, it is important to develop methods to increase storage capacitance.

One method employed to increase storage capacitance is to widen the bottom portion of the trench, thus, increasing the surface area and creating a bottle-shaped capacitor. FIGS. 1A˜1I are schematic diagrams of a conventional method of fabricating a bottle-shaped trench.

In FIG. 1A, a pad layer 110 is formed on part of a silicon substrate 100. The pad layer 110 can be composed of a silicon nitride layer (not shown) and a pad oxide layer (not shown) formed on the substrate 100. Using the pad layer 110 as a mask, a dry etching process is performed to form a trench 120 in the substrate 100. The trench 120 has an upper portion 130 and a lower portion 140.

In FIG. 1A, a first silicon oxide layer 150, a silicon nitride layer 160, an amorphous silicon layer 170 and a second silicon oxide layer 180 are sequentially formed on the surface of the trench 120. The first silicon oxide layer 150 is a SiO₂ layer with a thickness of about 28 Å, formed by thermal oxidation. The silicon nitride layer 160 is a Si₃N₄ layer with a thickness of about 80 Å, formed by deposition. The amorphous silicon layer 170 is formed by deposition, which has a thickness of about 220 Å. The second silicon oxide layer 180 is a SiO₂ layer with a thickness of about 80 Å, formed by deposition.

In FIG. 1B, a photoresist recess etching process is performed to form a photoresist layer 190 in the trench 120 located at the lower portion 140.

In FIG. 1C, using the photoresist layer 190 as a mask, the silicon oxide layer 180 located at the upper portion 130 is removed. The photoresist layer 190 is then removed.

In FIG. 1D, a rapid thermal nitridation procedure is performed to form a thin silicon nitride film 192 of about 20 Å on the surface of the amorphous silicon layer 170 located at the upper portion 130.

In FIG. 1E, using the thin silicon nitride film 192 as a mask, the remaining silicon oxide layer 180 is removed. Using the thin silicon nitride film 192 as a mask, the amorphous silicon layer 170 located at the lower portion 140 is then removed.

In FIG. 1F, the thin silicon nitride film 192 and the silicon nitride layer 160 located at the lower portion 140 are removed. Then, the amorphous silicon layer 170 located at the upper portion 130 is removed. At this point, the first silicon oxide layer 150 and the silicon nitride layer 160 located at the upper portion 130 remain in the trench 120.

In FIG. 1G, using the silicon nitride layer 160 as a mask, the first silicon oxide layer 150 located at the lower portion 140 is removed to expose the surface of the trench 120 at the lower portion 140.

In FIG. 1H, using the silicon nitride layer 160 as a mask, a wet etching procedure (also called a wet bottle etching procedure) is performed to etch the silicon substrate 100 in the trench 120 at the lower portion 140. A bottle-shaped space 194 within the trench 120 is thus formed.

The remaining silicon nitride layer 160 and the remaining silicon oxide layer 150 are then removed. Thus, a bottle-shaped trench is obtained, as shown as FIG. 1I.

The conventional method for fabricating the bottle-shaped trench is very complicated, and expensive to manufacture. In addition, the first silicon oxide layer 150, the silicon nitride layer 160, the amorphous silicon layer 170, and the second silicon oxide layer 180 are all formed on the surface of the trench 120, thereby hindering reduction in trench geometry and size thereof.

### SUMMARY OF THE INVENTION

An object of the present invention is to provide a method of forming a bottle-shaped trench.

In order to achieve these objects, the present invention provides a method of forming a bottle-shaped trench. A trench is formed in a substrate, wherein the trench has a surface with an upper portion and a lower portion beneath the upper portion. A dielectric layer (e.g. SiO₂ layer) is formed on the trench surface at the lower portion. Using the dielectric layer as a mask, a nitridation procedure is performed to form a nitride film on the trench surface at the upper portion. The dielectric layer is removed. Using the nitride film as a mask, an isotropic etching procedure is performed to form a space in the trench at the lower portion, thus, a bottle-shaped trench is formed.

The present invention improves on the prior art in that the present method uses the nitridation procedure to form the nitride film on the trench surface at the upper portion. Using the nitride film as a mask, isotropic etching is then performed to form a bottle-shaped space in the trench at the lower portion. Thus, the present invention simplifies the conventional process and reduces manufacturing costs. Moreover, the present invention is suitable for 0.1 mm trench technology, thereby achieving the goal of IC shrinkage and ameliorating the disadvantages of the prior art.

### BRIEF DESCRIPTION OF THE DRAWINGS

The present invention can be more fully understood by reading the subsequent detailed description in conjunction with the examples and references made to the accompanying drawings, wherein:

FIGS. 1A-1I are sectional views, according to the conventional process, of forming a bottle-shaped trench in a substrate; and

FIGS. 2˜9 are sectional views, according to the present invention, of forming a bottle-shaped trench in a substrate.

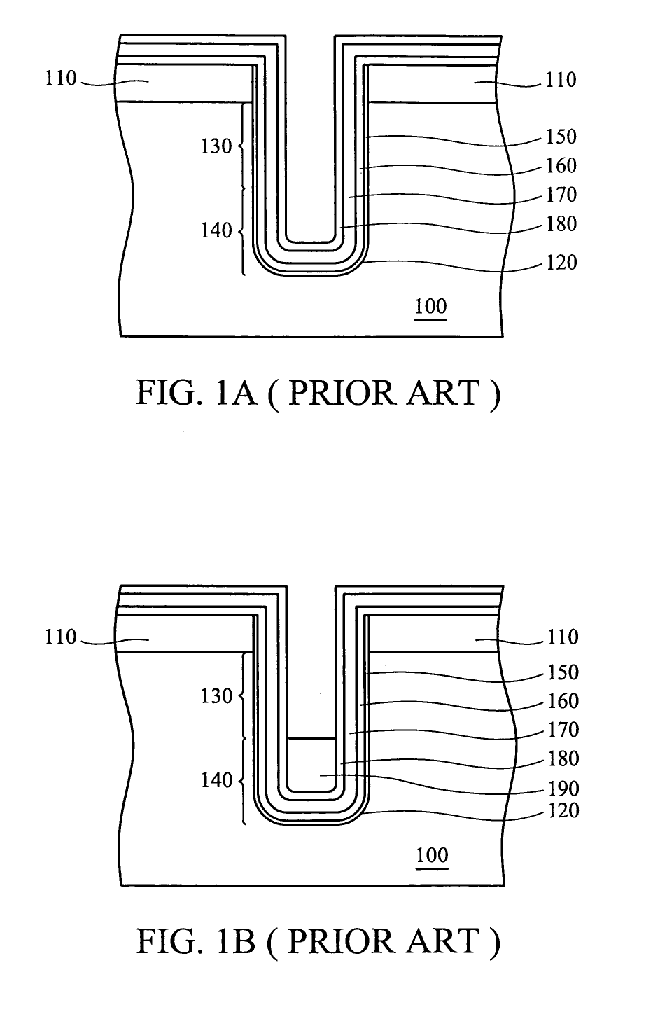

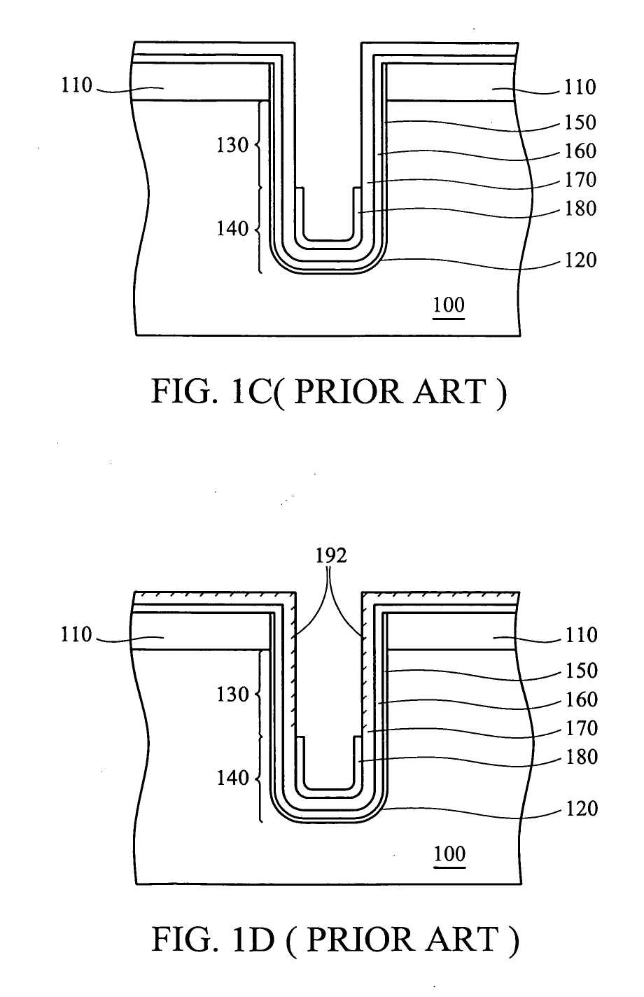

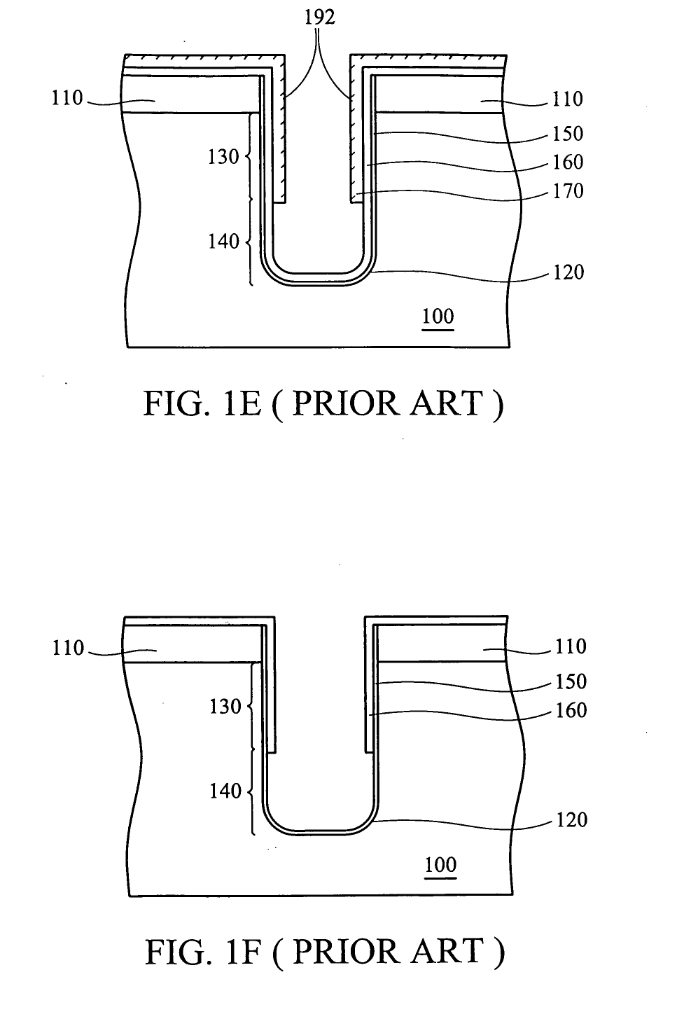

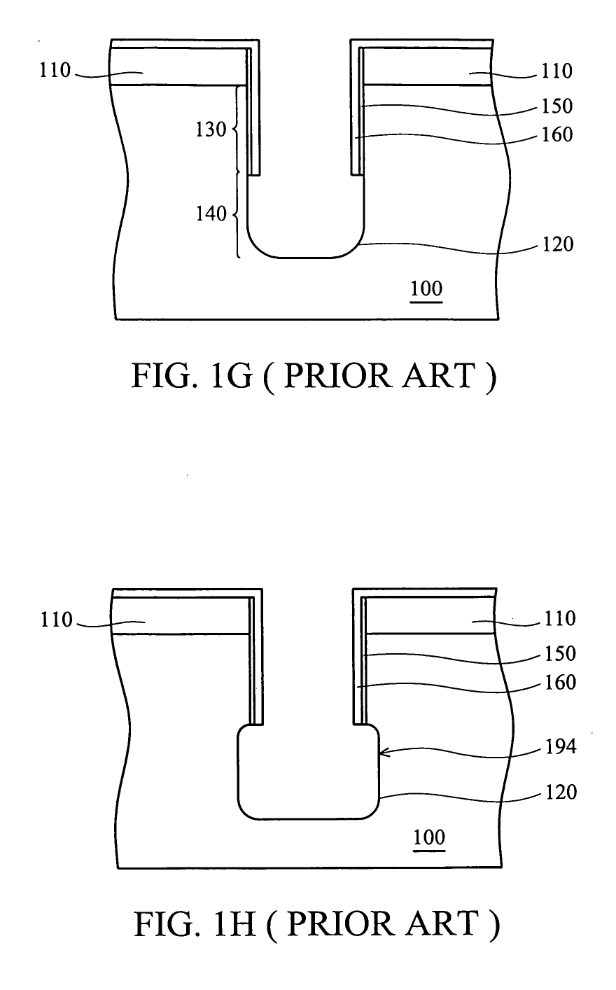

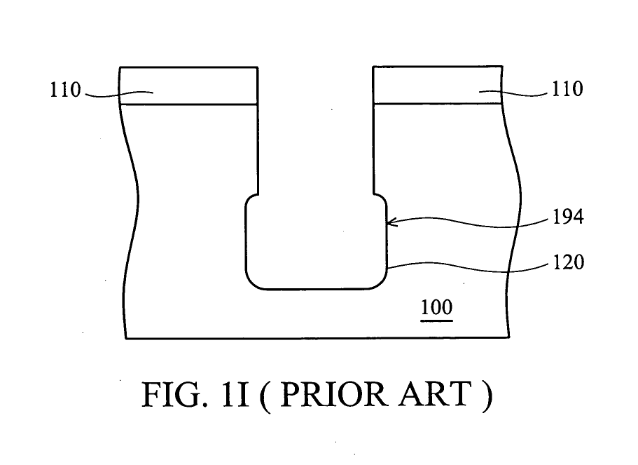

### DETAILED DESCRIPTION OF THE INVENTION

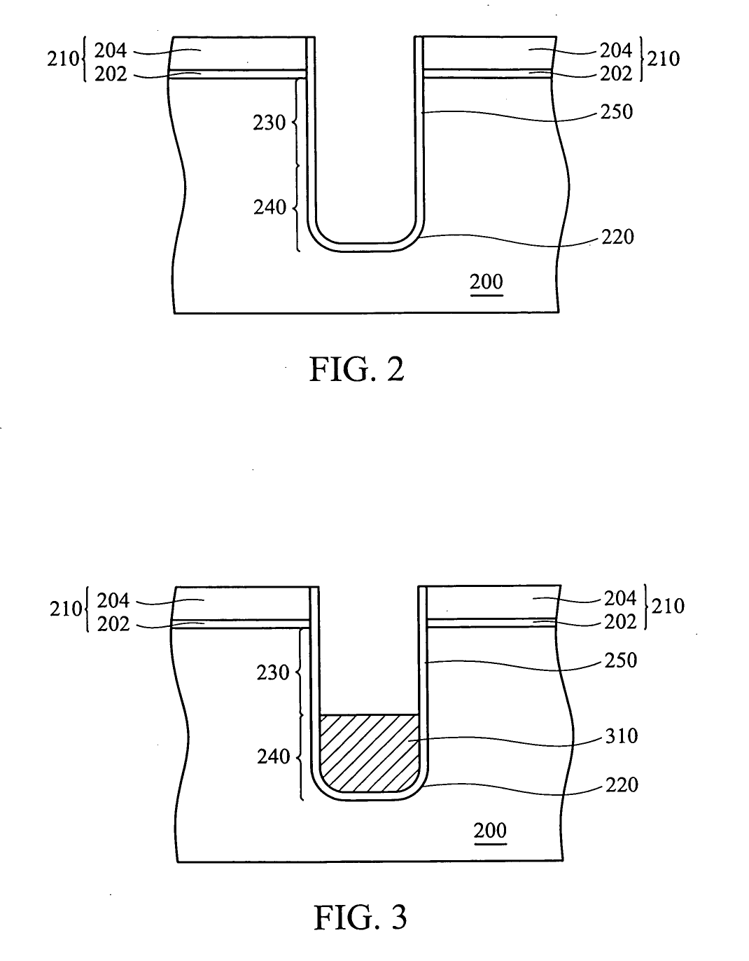

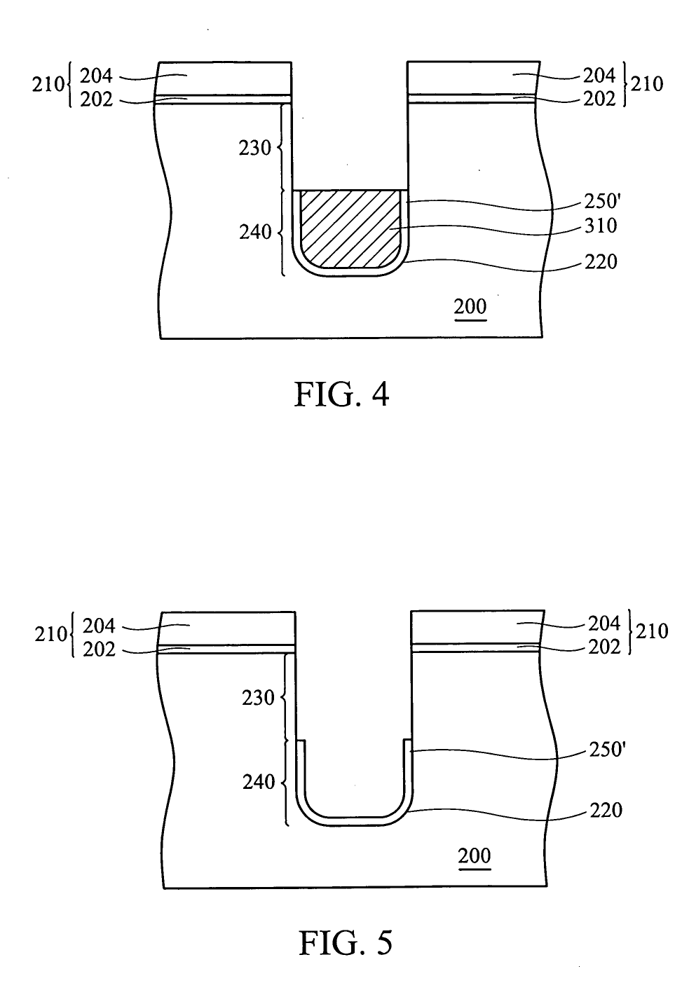

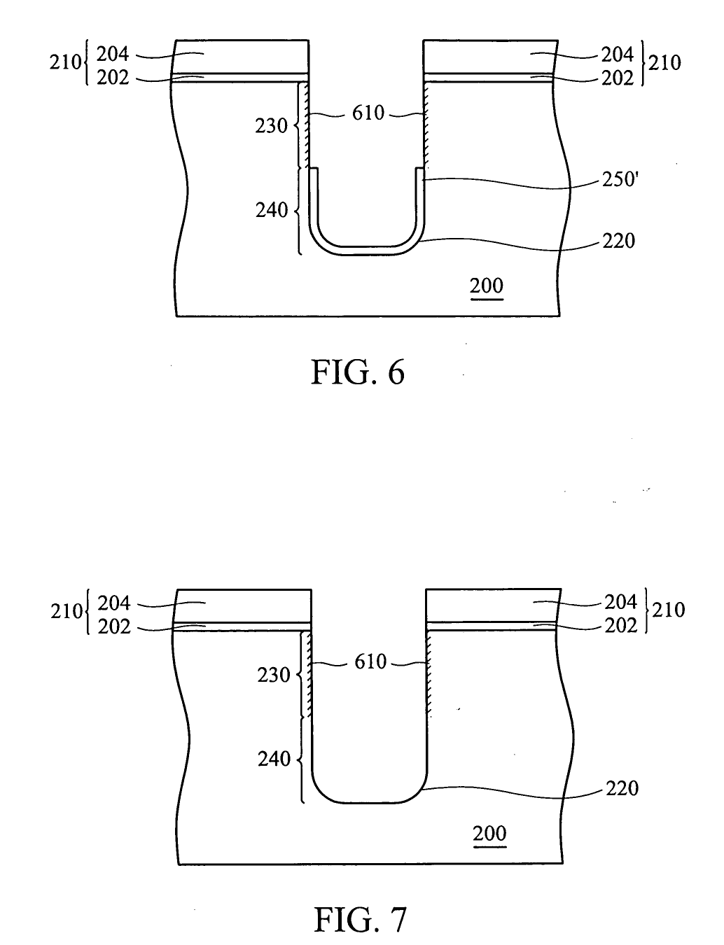

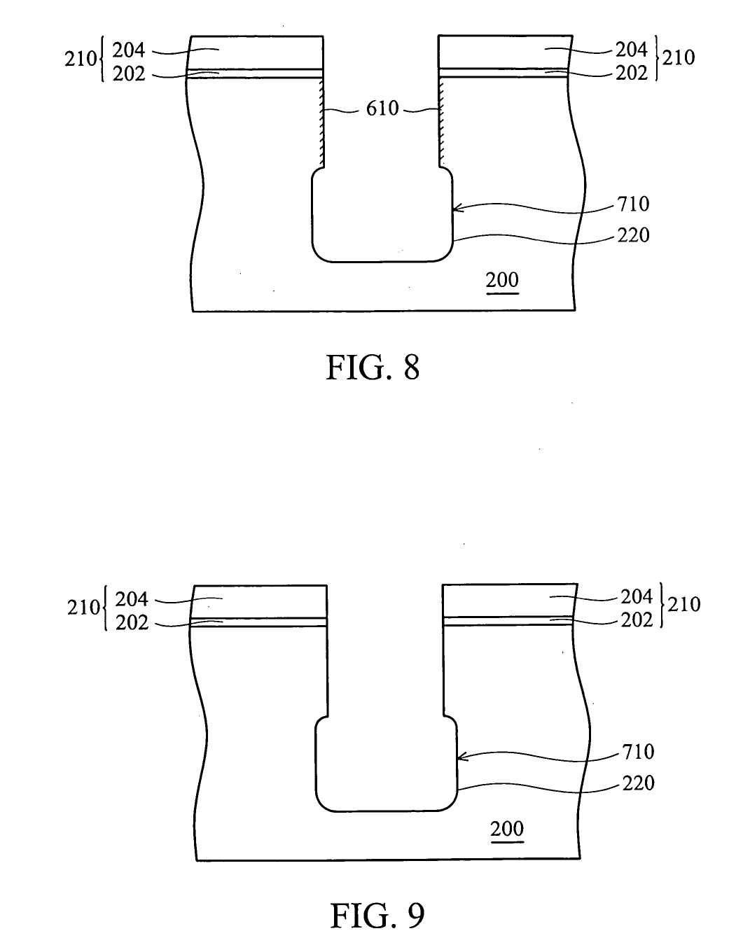

An embodiment according to the present invention will be explained with reference to FIGS. 2˜9.

In FIG. 2, a silicon substrate 200, such as a single crystal silicon wafer, is provided. A pad stack 210 composed of a pad oxide layer (such as SiO₂) 202 and a silicon nitride layer (such as Si₃N₄) layer 204 is formed on part of the substrate 200. Next, a dry etching process using the pad stack 210 as a mask is performed to form a deep trench 220 in the substrate 200. The trench 220 has a surface with an upper portion 230 and a lower portion 240 beneath the upper portion 230.

In FIG. 2, a dielectric layer 250 is formed on the surface of the trench 220. The dielectric layer 250 can be a SiO₂ layer formed by thermal oxidation, LPCVD, SACVD, or atomic layer deposition. The thickness of the dielectric layer 250 is about 10˜200 Å.

In FIG. 3, the trench 220 is filled with a photoresist layer (not shown). Next, the photoresist layer (not shown) is partially etched back so that a photoresist layer 310 remains on the dielectric layer 250 at the lower portion 240. This step is called a photoresist recess etching process.

In FIG. 4, using the remaining photoresist layer 310 as a mask, the dielectric layer 250 located at the upper portion 230 is etched to leave a remaining dielectric layer 250′ on the trench surface at the lower portion 240. Thus, the trench surface at the upper portion 230 is exposed.

In FIG. 5, the remaining photoresist layer 310 is removed by, for example, wet etching.

In FIG. 6, using the remaining dielectric layer 250′ as a mask, a rapid thermal nitridation (RTN) procedure is performed to form a silicon nitride (Si₃N₄) film 610 on the trench surface at the upper portion 230. An operating temperature of the rapid thermal nitridation procedure is, for example, 800˜1200° C. The thickness of the silicon nitride film 610 is about 15˜30 Å. It should be noted that the silicon nitride film 610 formed by RTN is very dense because the trench surface is a single crystal silicon structure. Thus, the silicon nitride film 610 is well suited to serve as an etch stop layer.

In FIG. 7, the remaining dielectric layer 250′ is then removed by, for example, wet etching. Thus, the trench surface at the lower portion 240 is exposed.

In FIG. 8, using the silicon nitride film 610 and the pad layer 210 as a mask, an isotropic etching procedure, such as wet etching, is performed to etch the exposed substrate 200 at the lower portion 240. Thus, a bottle-shaped space 710 is formed in the trench 220.

In FIG. 9, the silicon nitride film 610 is then removed. A bottle-shaped trench is thus obtained.

Moreover, a trench capacitor (not shown) composed of a top electrode, a dielectric layer and a low electrode can be formed in the bottle-shaped trench 710. The formation of the trench capacitor (not shown) uses a conventional process, for example, disclosed in U.S. Pat. No. 6,326,261. In order to avoid obscuring aspects of the present invention, the trench capacitor process is not described here.

The present invention uses the nitridation procedure (i.e. RTN) to form the nitride film on the trench surface at the upper portion. Using the nitride film as a mask, an isotropic etching procedure is then performed to form a bottle-shaped space in the trench at the lower portion. Thus, the present invention simplifies the conventional process, thereby reducing manufacturing costs. In addition, the present invention is well suited to the 0.1 mm trench technology, thereby achieving the goal of IC size reduction and ameliorating the disadvantages of the prior art.

Finally, while the invention has been described by way of example and in terms of the above, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A method of forming a bottle-shaped trench, comprising the steps of:
providing a substrate;
forming a trench in the substrate, wherein the trench has a trench surface with an upper portion and a lower portion beneath the upper portion;
forming a dielectric layer on the trench surface at the lower portion;
using the dielectric layer as a mask, performing a nitridation procedure to form a nitride film on the trench surface at the upper portion;
removing the dielectric layer; and
using the nitride film as a mask, performing an isotropic etching procedure to form a space in the trench at the lower portion.

2. The method according to claim 1, wherein the substrate comprises single crystal silicon.

3. The method according to claim 1, wherein the dielectric layer is an oxide layer formed by thermal oxidation or CVD.

4. The method according to claim 1, wherein a thickness of the dielectric layer is 10˜200 Å.

5. The method according to claim 1, wherein the formation of the dielectric layer on the trench surface at the lower portion comprises the steps of:
forming a conformal dielectric layer on the trench surface;
filling a photoresist layer in the trench;
partially etching back the photoresist layer to form a remaining photoresist layer on the dielectric layer at the lower portion;
using the remaining photoresist layer as a mask, removing the dielectric layer at the upper portion; and
removing the remaining photoresist layer.

6. The method according to claim 1, wherein the nitridation procedure is a rapid thermal nitridation (RTN) procedure.

7. The method according to claim 6, wherein an operating temperature of the rapid thermal nitridation procedure is 800˜1200° C.

8. The method according to claim 1, wherein a thickness of the nitride film is 15˜30 Å.

9. The method according to claim 1, wherein the formation of the trench comprises the steps of:
forming a pad layer on part of the substrate; and
using the pad layer as a mask, removing part of the substrate to form the trench therein.

10. The method according to claim 9, wherein the pad layer comprises a pad oxide layer and a nitride layer.

11. A method of forming a bottle-shaped trench, comprising the steps of:
providing a silicon substrate, wherein the silicon substrate comprises single crystal silicon;
forming a trench in the silicon substrate, wherein the trench has a trench surface with an upper portion and a lower portion beneath the upper portion;
forming a conformal dielectric layer on the trench surface;
filling a photoresist layer in the trench;
partially etching back the photoresist layer to form a remaining photoresist layer on the dielectric layer at the lower portion;
using the remaining photoresist layer as a mask, removing the dielectric layer at the upper portion to leave a remaining dielectric layer on the trench surface at the lower portion;
removing the remaining photoresist layer;
using the remaining dielectric layer as a mask, performing a rapid thermal nitridation (RTN) procedure to form a Si₃N₄ film on the trench surface at the upper portion;
removing the remaining dielectric layer; and
using the Si₃N₄ film as a mask, performing a wet etching procedure to form a space in the trench at the lower portion.

12. The method according to claim 11, wherein a thickness of the conformal dielectric layer is a SiO₂ layer having a thickness of 10˜200 Å formed by thermal oxidation or CVD.

13. The method according to claim 11, wherein an operating temperature of the rapid thermal nitridation procedure is 800˜1200° C.

14. The method according to claim 11, wherein a thickness of the Si₃N₄ film is 15˜30 Å.

15. The method according to claim 11, wherein the formation of the trench comprises the steps of:
forming a pad layer on part of the substrate; and
using the pad layer as a mask, removing part of the substrate to form the trench therein.

16. The method according to claim 15, wherein the pad layer comprises a pad oxide layer and a nitride layer.
